(19) United States
(12) Patent Application Publication
(10) Pub. No.: US 2014/0346510 A1
(43) Pub. Date: Nov. 27, 2014

(54) DEVICE STRUCTURE SUITABLE FOR PARALLEL TEST

(71) Applicant: Shanghai Huali Microelectronics Corporation, Shanghai (CN)

(72) Inventors: Binfeng Yin, Shanghai (CN); Min Zhao, Shanghai (CN); Ke Zhou, Shanghai (CN)

(73) Assignee: Shanghai Huali Microelectronics Corporation, Shanghai (CN)

(21) Appl. No.: 14/083,885

(22) Filed: Nov. 19, 2013

(30) Foreign Application Priority Data
May 23, 2013 (CN) 201310196280.3

(51) Int. Cl. H01L 21/66

(52) U.S. Cl. CPC H01L 22/30
USPC 257/48

(57) ABSTRACT

A device structure suitable for parallel test is disclosed, which includes a main body and an anti-crosstalk structure. The main body includes a first well formed in a substrate, the first well defining a boundary of the main body in the substrate. The anti-crosstalk structure is a second well formed in the substrate and surrounding the first well of the main body. The second well has a conductivity type opposite to a conductivity type of the first well and has a depth greater than a depth of the first well. The present invention is capable of preventing the interference between leakage currents generated in bases of the same conductivity type of different such device structures during a parallel test, thereby allowing the leakage currents to be correctly measured and improving the reliability of measurement result and the test efficiency.

### CROSS-REFERENCES TO RELATED APPLICATIONS

This application claims the priority of Chinese patent application number 201310196280.3, filed on May 23, 2013, the entire contents of which are incorporated herein by reference.

### TECHNICAL FIELD

The present invention relates to semiconductor device testing, and more particularly, to a device structure suitable for parallel test and a parallel test block incorporating a plurality of such device structures.

### BACKGROUND

A typical semiconductor device fabrication process essentially consists of four processing steps, i.e., wafer fabrication, wafer testing, integrated circuit (IC) packaging and final testing. The wafer fabrication step is to form identical circuits each containing a collection of electronic components on a wafer. Next, the circuits are each individually electrically tested with a wafer test probe to identify bad ones which are to be discarded subsequently. After that, the wafer is sliced into dies, and those bearing circuits that have passed the test are formed into IC chips in the next IC packaging step where they are packaged and connected to external circuits. Finally, each packaged IC chip further undergoes an electrical test to make sure that the IC chip can function properly.

To meet the contemporary demand for increasing the number of circuits that can be tested at once and decreasing the testing time, there has been developed a parallel test system which can simultaneously test multiple circuits formed on the same wafer. The parallel test system includes a wafer prober equipped with a probe card containing a plurality of probes each made contact with a corresponding target circuit and a test software program which instructs the wafer prober to verify the induced electric current in the circuit by applying a voltage to each target circuit.

In the existing semiconductor device fabrication processes, in an area of a circuit formed on a wafer, most electronic component regions are defined as P-wells, except those regions such as P-type metal-oxide-semiconductor (PMOS) transistor regions and deep well regions. FIG. 1 shows a typical N-type metal-oxide-semiconductor (NMOS) transistor 10, which includes: a substrate 100; a P-well 101 formed in the substrate 100; a gate structure 102 located on the surface of the substrate 100 above the P-well 101; a source 103 and a drain 104 formed in the P-well 101 and situated on two opposite sides of the gate structure 102; and two bases 105 and 106 formed in the P-well 101, the bases being adjacent to and isolated, by first shallow trench isolations 107 and 108, from the source 103 and the drain 104, respectively. In this design, as the P-well 101 and the bases 105 and 106 have the same conductivity type, in the event that a testing voltage is applied to the NMOS transistor 10, a leakage current generated in the P-well 101 and under the gate structure 102 will flow into the base 106 (as indicated by the arrow in FIG. 1), even blocked by the shallow trench isolations 107 and 108. As a result, the leakage current can be detected in the base 106. However, as most component regions on the wafer being tested are P-well regions except a small number of N-well ones, base leakage currents in all the NMOS transistors are eventually connected in series. For example, when the two neighboring NMOS transistors 10 and 20 shown in FIG. 2, each having the same structure as described for the NMOS transistor of FIG. 1 and isolated from each other by a shallow trench isolation 40, are provided simultaneously with a testing voltage to test leakage currents in their bases 106 and 205, the generated base leakage currents in the two devices will interfere with each other (as indicated by the arrows in FIG. 2) and cannot be detected correctly. This is detrimental to some applications where base leakage current is taken as a key indicator for assessing the reliability of the circuit being tested.

### SUMMARY OF THE INVENTION

The present invention addresses the above described base leakage current crosstalk issue of the prior art that is disadvantageous to reliability assessment by presenting a device structure suitable for parallel test.

In a first aspect of the invention, there is provided a device structure suitable for parallel test. The device structure includes a main body and an anti-crosstalk structure. The main body includes a first well formed in a substrate, the first well defining a boundary of the main body in the substrate. The anti-crosstalk structure is a second well, formed in the substrate and surrounding the first well of the main body. The second well has a conductivity type opposite to a conductivity type of the first well and has a depth greater than a depth of the first well.

According to an embodiment, the device structure may further include:

a gate structure located on a surface of the substrate above the first well;

a source and a drain formed in the first well and situated on respective two opposite sides of the gate structure;

a first base formed in the first well and isolated from the source by a first shallow trench isolation; and

a second base formed in the first well and isolated from the drain by a second shallow trench isolation.

According to an embodiment, the device structure may further include a third shallow trench isolation for isolating the first well from the second well,

According to an embodiment, the first well may be a P-well with the second well being an N-well. Alternately, the first well can be an N-well with the second well being a P-well.

According to an embodiment, each of the source and the drain may have a conductivity type same as the conductivity type of the second well.

According to an embodiment, each of the first base and the second base may have a conductivity type same as the conductivity type of the first well.

According to an embodiment, the second well may have a cross-section of rectangular ring or circular ring.

In a second aspect of the invention, there is provided a parallel test block including a plurality of device structures arranged in parallel, each device structure including a first well formed in a substrate, each first well defining a boundary of a corresponding one of the plurality of device structures in the substrate, wherein the first wells of every two neighboring device structures are isolated from each other by a second well having a conductivity type opposite to a conductivity type of each of the first wells and having a depth greater than a depth of each of the first wells.

The present invention has the following advantage over the prior art:

By surrounding the first well of each device structure with a ring-shaped second well having an opposite conductivity type to the first well to isolate bases of different device structures, interference between leakage currents generated in the bases of the device structures during a parallel test are prevented, thereby allowing the leakage currents to be correctly measured and hence improving the reliability of measurement result and the test efficiency.

### BRIEF DESCRIPTION OF DRAWINGS

FIG. 1 shows a cross-sectional view illustrating a conventional device structure for parallel test.

FIG. 2 shows a cross-sectional view illustrating neighboring two of the conventional device structures for parallel test.

FIG. 3 shows a cross-sectional view of a device structure suitable for parallel test in accordance with one embodiment of the present invention.

FIG. 4 shows a top view of a parallel test block in accordance with one embodiment of the present invention.

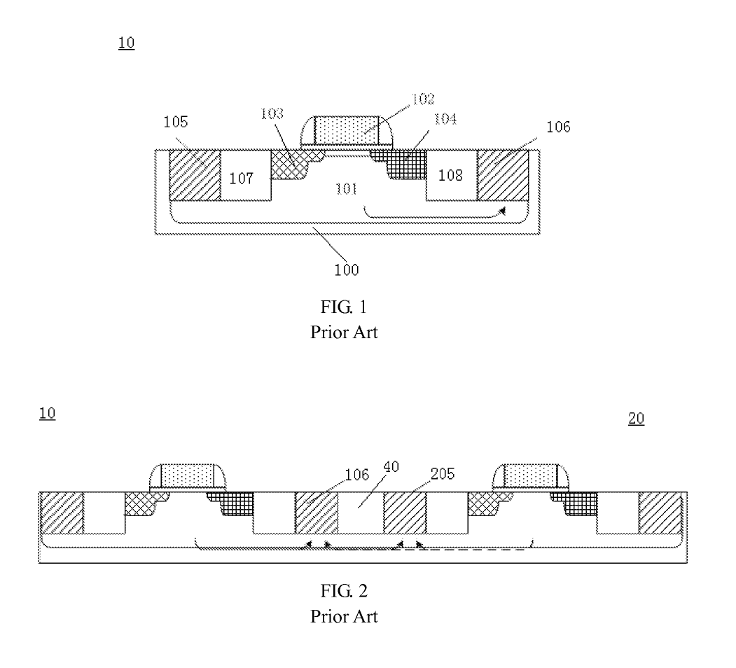

### DETAILED DESCRIPTION

The present invention will be further described with reference to the following detailed description of exemplary embodiments, taken in conjunction with the accompanying drawings. Features and advantages of the invention will be apparent from the following detailed description, and from the appended claims. Note that all the drawings are presented in a very simple form and not drawn precisely to scale. They are provided solely to facilitate the description of the exemplary embodiments of the invention in a convenient and clear way.

The present invention is to provide a device structure suitable for parallel test, which includes a second well having an opposing conductivity type to a first well formed under a gate structure of the device structure. The second well can prevent interference between leakage currents generated in bases of a plurality of the device structures undergoing a parallel test, thereby allowing for correct measurement of the leakage currents.

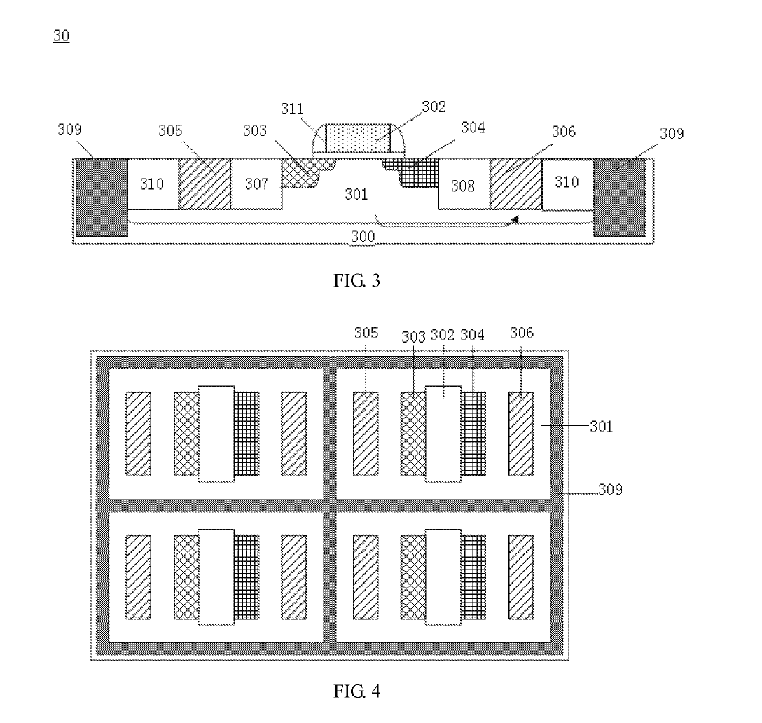

FIG. 3 shows a cross-sectional view of a device structure suitable for parallel test in accordance with one embodiment of the present invention. The device structure is indicated at 30 and includes:

a substrate 300;

a first well 301 formed in the substrate 300;

a gate structure 302 located on surface of the substrate 300 above the first well 301;

a source 303 and a drain 304 formed in the first well 301 and situated on two opposite sides of the gate structure 302;

a first base 305 formed in the first well 301, the first base 305 situated adjacent to the source 303 and isolated therefrom by a first shallow trench isolation 307;

a second base 306 formed in the first well 301, the second base 306 situated adjacent to the drain 304 and isolated therefrom by another first shallow trench isolation 308; and

a second well 309 surrounding all of the first well 301, the source 303, the drain 304 and the first and second bases 305 and 306 and being isolated therefrom by a second shallow trench isolation 310, the second well 309 having an opposing conductivity type to the first well 301.

In this embodiment, spacers 311 are formed on opposite sides of the gate structure 302, and each of the first and second shallow trench isolations 307, 308 and 310 is formed using typical Shallow Trench Isolation (STI) processes.

In this embodiment, the first well 301 is a P-type well, while both of the source 303 and the drain 304 are N-type. Additionally, the first and second bases 305 and 306 have the same conductivity type (i.e., P-type) as the first well 301, whilst the second well 309 has the opposing conductivity type (i.e., N-type) to the first well 301.

FIG. 4 shows a top view of a parallel test block incorporating a plurality of the device structures of the above described embodiment. As illustrated, the second well 309 of each of the device structures may be ring-shaped (having a cross-section of rectangular ring as shown in FIG. 4) and surrounds the first well 301, the source 303, the drain 304 and the first and second bases 305 and 306 of the corresponding device structure. Note that the first and second shallow trench isolations 307, 308 and 310 are not shown in FIG. 4 for simplicity. Advantageously, individually isolated by the second wells 309, a leakage current generated in the first well 301 in each device structure of the parallel test block during a parallel test will not interfere with that in any other identical device structure, thereby allowing the leakage current generated in every device structure to be correctly measured.

It should be appreciated that it is within the scope of the present invention to employ the second wells 309 at different positions from as shown in FIG. 4 to meet practical needs, as long as they isolate counterpart components of different device structures from each other to facilitate their testing. In the case of P-type first wells 301, the second wells 309 may be doped with phosphorous, arsenic, antimony, or other N-type ions, Dopant concentration and width of the second wells 309 may be properly determined according to size of the device structures, process requirements, equipment and process conditions and etc. Furthermore, it is preferable that the second wells 309 have a depth greater than a depth of the first wells 301 and is as greater as applicable, because a greater depth of the second wells 309 can lead to a better isolation.

In other embodiments, the second wells 309 may have a cross-section of circular ring or another proper shape.

When the parallel test block of the present invention undergoes a parallel test, the second wells having the opposing conductively type that individually isolate the first wells of the device structures can block a base leakage current generated in any device to flowing into adjacent devices, thereby preventing crosstalk of base leakage currents in different devices. Therefore, the accuracy of base leakage current measurement can be improved while not decreasing measurement speed and the measurement reliability can be advantageously improved.

From the above description, it can be understood that this invention has the following advantage, i.e., by surrounding the first well of each device structure with a second well having an opposing conductivity type to the first well to isolate bases having the same conductivity type of different device structures, interference between leakage currents generated in the bases of the devices during a parallel test are prevented, thereby allowing the leakage currents to be correctly measured and hence improving the reliability of measurement result and the test efficiency.

While preferred embodiments have been illustrated and described above, it should be understood that they are not intended to limit the invention in any way. It is also intended that the appended claims cover all variations and modifications made in light of the above teachings by those skilled in the art.

What is claimed is:

1. A device structure suitable for parallel test, comprising: a main body and an anti-crosstalk structure, wherein:
the main body includes a first well formed in a substrate, the first well defining a boundary of the main body in the substrate; and
the anti-crosstalk structure is a second well formed in the substrate, the second well surrounding the first well, having a conductivity type opposite to a conductivity type of the first well and having a depth greater than a depth of the first well.

2. The device structure of claim 1, wherein the main body further includes:
a gate structure located on a surface of the substrate above the first well;
a source and a drain formed in the first well and situated on respective two opposite sides of the gate structure;
a first base formed in the first well and isolated from the source by a first shallow trench isolation; and
a second base formed in the first well and isolated from the drain by a second shallow trench isolation.

3. The device structure of claim 2, further comprising a third shallow trench isolation for isolating the first well from the second well.

4. The device structure of claim 1, wherein the first well is a P-well and the second well is an N-well.

5. The device structure of claim 1, wherein the first well is an N-well and the second well is a P-well.

6. The device structure of claim 2, wherein each of the source and the drain has a conductivity type same as the conductivity type of the second well.

7. The device structure of claim 2, wherein each of the first base and the second base has a conductivity type same as the conductivity type of the first well.

8. The device structure of claim 1, wherein the second well has a cross-section of rectangular ring or circular ring.

9. A parallel test block comprising a plurality of device structures arranged in parallel, each device structure including a first well formed in a substrate, each first well defining a boundary of a corresponding one of the plurality of device structures in the substrate, wherein the first wells of every two neighboring device structures are isolated from each other by a second well having a conductivity type opposite to a conductivity type of each of the first wells and having a depth greater than a depth of each of the first wells.

10. The parallel test block of claim 9, wherein each device structure further includes:
a gate structure located on a surface of the substrate above the first well;
a source and a drain formed in the first well and situated on two opposite sides of the gate structure;
a first base formed in the first well and isolated from the source by a first shallow trench isolation; and
a second base formed in the first well and isolated from the drain by a second shallow trench isolation.

11. The parallel test block of claim 10, further comprising third shallow trench isolations each for isolating the first well from a corresponding second well.

12. The parallel test block of claim 9, wherein, of each device structure, the first well is a P-well and the second well is an N-well.

13. The parallel test block of claim 9, wherein, of each device structure, the first well is an N-well and the second well is a P-well.

14. The parallel test block of claim 10, wherein, of each device structure, each of the source and the drain has a conductivity type same as the conductivity type of a corresponding second well.

15. The parallel test block of claim 10, wherein, of each device structure, each of the first base and the second base has a conductivity type same as the conductivity type of the first well.

16. The parallel test block of claim 9, wherein each second well has a cross-section of rectangular ring or circular ring.
